(19) United States
(12) Patent Application Publication
(10) Pub. No.: US 2005/0016575 A1
(43) Pub. Date: Jan. 27, 2005

(54) Field emission based thermoelectric device

(76) Inventors: Nalin Kumar, Fort Worth, TX (US); Paul Henry Cutler, State College, PA (US); Nicholas Matthew Miskovsky, State College, PA (US); Moon S. Chung, Ulsan (KR)

Correspondence Address: Nalin Kumar, 6808 Meadows West Dr S, Fort Worth, TX, 76132, US

(21) Appl. No.: 10/866,429

(22) Filed: Jun. 12, 2004

Related U.S. Application Data
(60) Provisional application No. 60/478,899, filed on Jun. 13, 2003.

(51) Int. Cl. H01L 35/30

(52) U.S. Cl. 136/205

(57) ABSTRACT

This invention describes novel architectures for enhancing the efficiency of thermoelectric devices by incorporating high thermal resistivity and high electrical conductivity sections based on field emission devices. The uses of such devices include coolers and electricity generators.

### CROSS-REFERENCE TO RELATED APPLICATIONS

This application claims the benefit under 35 U.S.C. 119(e) from U.S. Provisional Application 60/478,899, filed Jun. 13, 2003.

### STATEMENT REGARDING FEDERALLY SPONSORED RESEARCH OR DEVELOPMENT

No Government License Rights.

### BACKGROUND OF THE INVENTION—FIELD OF THE INVENTION

This invention lies in the field of thermoelectric and field emission devices and is particularly concerned with the device design of field emission enhanced thermoelectric effect chips useful for cooling and power generation applications.

### BACKGROUND OF THE INVENTION—PRIOR ART

### 1. Thermoelectric Technology

The thermoelectric (TE) phenomena involve the three effects known as the Seebeck effect, the Peltier effect and the Thomson effect. These effects explain the conversion of heat energy into electrical energy and vice versa. The TE phenomena has been known for a long time and has been described in detail in many books and review articles over the last 100 years.[1-3] In 1823, Thomas Seebeck discovered that a voltage drop appears across a metal with a temperature gradient. The thermocouples and thermoelectric power generators are based on this effect. In 1883, Heinrich Lenz showed the thermoelectric cooling effect by passing current through a junction made from wires of bismuth and antimony. Passing the current in one direction caused the junction to cool. On the other hand, the junction was heated when the current direction was reversed. This was a very important discovery, however, the TE effects remained a scientific curiosity until the 1950s when Abram Ioffe found that the doped semiconductors had much large cooling effect than other materials.[4]

### 2. Thermoelectric Power Generator

Similar to a thermocouple, the TE power generator is based on the Seebeck effect. When a steady temperature gradient is maintained along a finite conductor, the free carriers at the hot end will have greater kinetic energy and will diffuse to the cold end. The accumulation of these charge carriers results in a back electromotive force which opposes a further flow of charge carriers. The Seebeck voltage is the open circuit voltage when no current flows. To form a thermocouple, the junctions of two dissimilar conductors (or semiconductors due to their larger Seebeck coefficients, >100 microvolts per degree K) are maintained at two different temperatures, and an open circuit potential difference is developed. This potential difference depends on the temperature difference between the two junctions and the difference between the absolute Seebeck coefficients of the two materials.

A thermoelectric power generator consists of many thermocouples. Since a thermocouple produces low voltage and high current, a TE power generator uses a large number of thermocouples that are connected electrically in series and thermally in parallel. The module is heated at one end and is maintained at a higher temperature than the other end such that a voltage appears between the terminals of the generator. Without going through the details of the theory, in the case of TE device consisting of two arms made from n- and p-type semiconductors, the power conversion efficiency is determined by a figure of merit Z, given as

$$Z = \frac{{α}^{2} σ}{λ} \qquad ( 1 )$$

where α is the Seebeck constant of the two materials, σ is the electrical conductivity, and λ is the thermal conductivity. Since, the open circuit voltage increases with temperature difference, the factor ZT must be maximized. However, since Z also changes with temperature, it has been found that the factor ZT is a more useful figure of merit that Z in actual practice.

### 3. Thermoelectric Cooler

After a long and intensive period of development of many technologies, two main cooler technologies have emerged, namely: mechanical coolers incorporating moving parts, and thermoelectric coolers based on Peltier cooling effect.

As mentioned earlier, the electronic coolers are generally associated with Peltier or thermoelectric coolers (TEC) commonly used for electronic chip cooling and even small portable commercial coolers. After the discovery of semiconductor thermoelectrics, almost every known semiconductor was investigated and it was found that bismuth telluride alloys (Bi₂Te₃/Sb₂Te₃) were the best at room temperature. However, even at their best, they produce only moderate amount of cooling and have very poor efficiency because they are dictated by the same equations as the thermoelectric generator. Again, intuitively, this is due to the fact that the hot and cold junctions are thermally connected with the p and n type semiconductors. Higher the thermal conductivity, lower is the TEC efficiency due to heat leakage from the hot junction to the cold junction. Additionally, the efficiency drops significantly as the temperature difference between the hot and cold junctions increases. This effect also limits the maximum temperature difference that can be maintained between the hot and cold junctions. Due to these limitations, TECs have only found limited use in niche power/thermal management applications such as IR detector cooling, diode laser cooling and spacecraft cooling/electric generation.

### 4. Factors Affecting the TE Figure of Merit

The materials used to make a TE device determine its efficiency, and usefulness of a material is described by its figure of merit ZT, a dimensionless constant. Most materials have a ZT values between 0.4 and 1.3.[5] As a frame of reference with traditional efficiency figures, a ZT value of 3 would make TEC based home refrigerators economically competitive with compressor based refrigerators. Theoretically, there is no upper limit to the ZT.[6] However, the maximum value for ZT has been stuck around 1 in spite of serious efforts since the early 1960s.

To understand the key reason behind this lack of improvement in the coefficient of performance, let us look at the equation 1. As per equation 1, Z depends on the Seebeck coefficient (α), the electrical conductivity (σ) and the thermal conductivity (λ). Thus, good TE materials should have the following properties:
1. high Seebeck coefficients
2. high electrical conductivity
3. poor thermal conductivity

However, the ideal TE material does not exist because, unfortunately, no one has found a good thermoelectric material that has good electrical conductivity but has poor thermal conductivity at the same time. Most metals have high electrical conductivity, but also have very high thermal conductivity resulting in very low Z. Semiconductors possess larger seebeck coefficients and poorer electrical conductivity resulting in λ/σ greater than metals. This is why most TE devices currently use semiconductor materials. However, poor electrical conductivity of semiconductors results in high ohmic losses affecting overall efficiency.

After decades of research in almost all possible materials, it has been determined that lowering the thermal conductivity of the high Seebeck coefficient is the best way to reduce their thermal conductivity without affecting other parameters. The reason for this is the fact that high thermal conductivity of the materials forms a direct thermal path between the hot and the cold sides resulting in serious wastage of energy.

### 5. Electron Emission Based Coolers

The oldest field emission cooler concepts are based on the Nottingham effect that revolves around the fact that as electrons are emitted from any cathode, they leave with significant energy, thereby cooling the cathode. This is true for almost all cathodes. The Nottingham effect has been known for almost 60 years. It has also been demonstrated experimentally for cathodes at elevated temperature (around 1000 degree Celsius). However, this cooling is noticeable only at very high temperatures due to the fact that high temperatures are necessary to emit any electrons from a cathode. Furthermore, as the electrons are emitted from the surface, these electrons must be replaced from the external circuit. The difference in the energies of the emitted electrons and the replacement electrons determines the net cooling/heating per emitted electron. If the average energy of emitted electrons is less than that of replacement electrons, the net result is heating of the cathode. This is the case at T=0K (absolute zero). On the other hand, if the emitted electrons have higher energy (e.g. due to electron excitation at room temperature) than the replacement electrons, the cathode is cooled due to the emission process. However, for all practical field emission materials, Nottingham cooling effect does not start until elevated temperatures. It is due to these reasons that 60 years after Nottingham described this cooling effect, no practical room temperature cooler has been successfully fabricated.

Recently, Mahan et al. have theoretically proposed the use of thermionic emitters [7] for use in coolers and electric generators. Cooling is obtained by thermionic emission of electrons over periodic barriers in a multilayer geometry. However, this type of device is difficult to fabricate and its operation at room temperature is very limited.

To bring the working temperature of these electronic coolers, several researchers have proposed use of very low work function materials. Edelson (U.S. Pat. Nos. 5,675,972, 5,722,242 and 5,994,638) describes vacuum diode based devices including vacuum diode heat pumps and vacuum thermionic generators, where the electrodes are coated with a low work function material called an electride. The fabrication of such a low work function thermionic cathode is very difficult with current techniques as has been pointed out by Edelson (U.S. Pat. No. 6,103,298), Cox (U.S. Pat. No. 6,214,651 B1) and Cox et al. (U.S. Pat. No. 6,117,344). More recently, Tavikhelidze, Edelson et al. have described methods for making a diode device with very small gap (preferably 5 nm) in between the device electrodes (U.S. Pat. Nos. 6,417,060 B2, 6,720,704 B1).

Recently, Ghoshal (U.S. Pat. Nos. 6,608,250 B2 and 6,740,600 B2) has taught a thermoelectric device with improved efficiency where tips made from thermoelectric tips provide a low resistive connection while minimizing thermal conduction between the electrical conductor and the device. In this configuration, the thermoelectric tips are directly coupled such that electrical current may pass, however, the tips increase the thermal resistivity. This approach potentially improves the device efficiency, but the device is difficult and expensive to fabricate due to difficulty in making tips from thermoelectric materials.

### BACKGROUND OF THE INVENTION—OBJECTS AND ADVANTAGES

It is, therefore, an object of the present invention is to provide improved thermoelectric devices for use in cooling and electricity generation applications.

It is another object of the present invention to provide devices that have high electrical conductivity and low thermal conductivity.

It is yet another object of the present invention to provide high efficiency thermoelectric devices that function with electrodes made from easily available high work function materials such as silicon.

It is yet another object of the present invention to provide high efficiency thermoelectric devices that operate at substantially large gap between the electrodes.

It is yet another object of the present invention to provide thermoelectric devices that can operate at cryogenic temperatures and maintain large temperature difference across their hot and cold sides.

### SUMMARY OF THE INVENTION

The present invention teaches improvements to the present thermoelectric cooling and power generation technology resulting in increased efficiency. In a preferred embodiment, a thermoelectric cooler is constructed with a high thermal resistivity device inserted in each leg of the thermoelectric cooler. In a preferred embodiment, the high thermal resistivity device is made from field emission tips and has high electrical conductivity. In a preferred embodiment, the high thermal resistivity device is made from silicon tips arranged in a triode configuration.

### BRIEF DESCRIPTION OF THE DRAWINGS

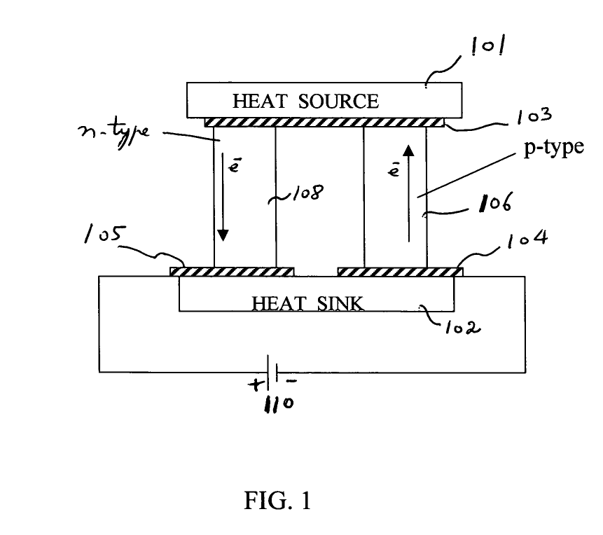

FIG. 1 is a high level block diagram of a Thermoelectric Cooler (TEC) device in accordance with the prior art.

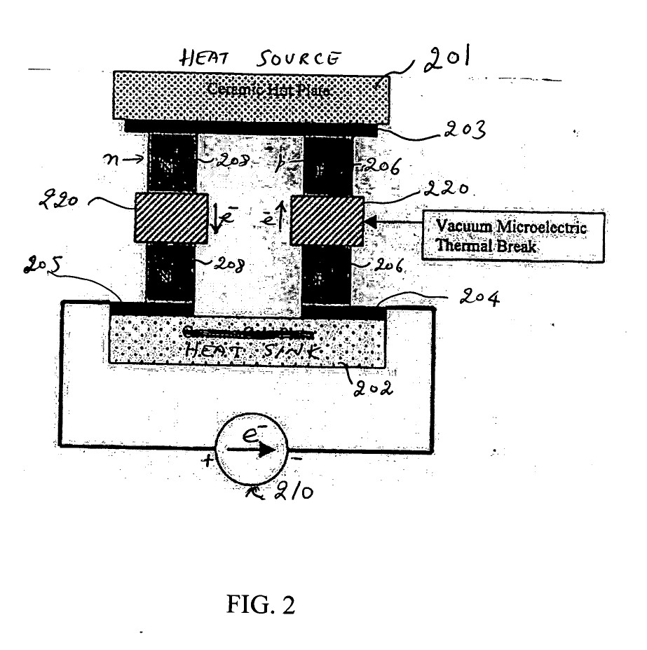

FIG. 2 shows a cross sectional view of a thermoelectric cooler in accordance with the present invention where high thermal resistivity and high electrical conductivity devices have been inserted in each of the TEC legs.

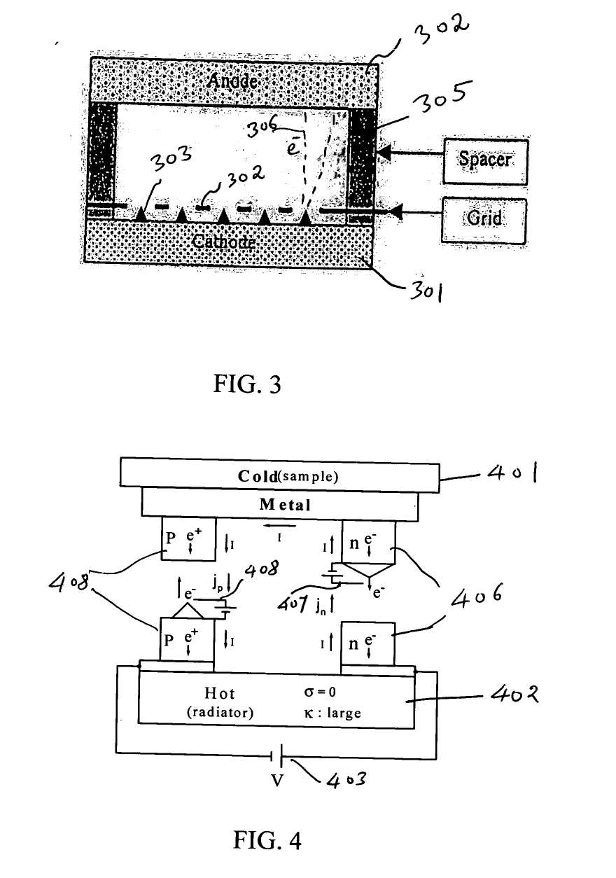

FIG. 3 shows a cross sectional view of a triode type field emission device with high thermal resistivity and high electrical conductivity.

FIG. 4 shows a schematic diagram of the thermoelectric cooler in accordance with the present invention used to show the principle governing the present invention.

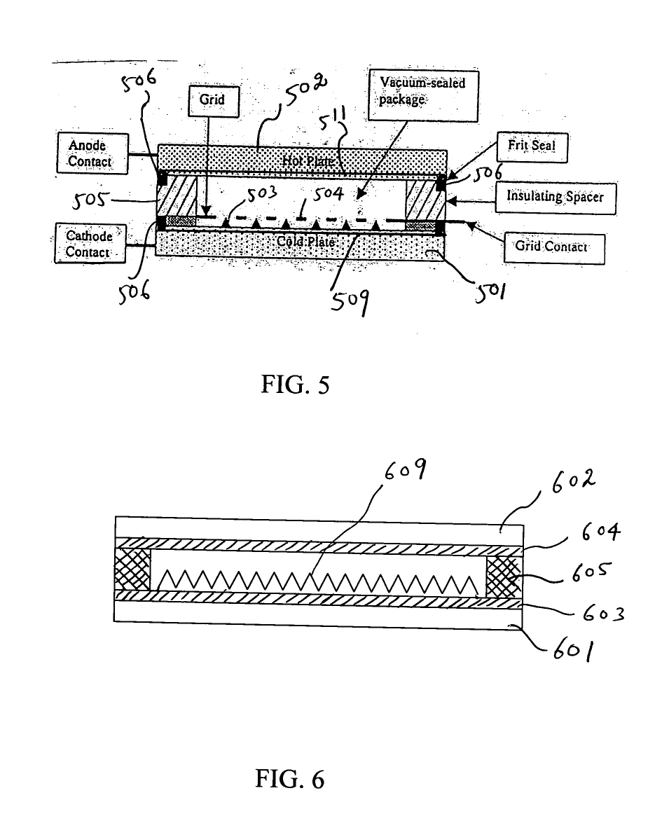

FIG. 5 shows an embodiment of the invention in which the high thermal resistivity device has been packaged into a self contained vacuum envelope.

FIG. 6 shows another embodiment of a high thermal resistivity device that uses field emission cathodes in a diode configuration.

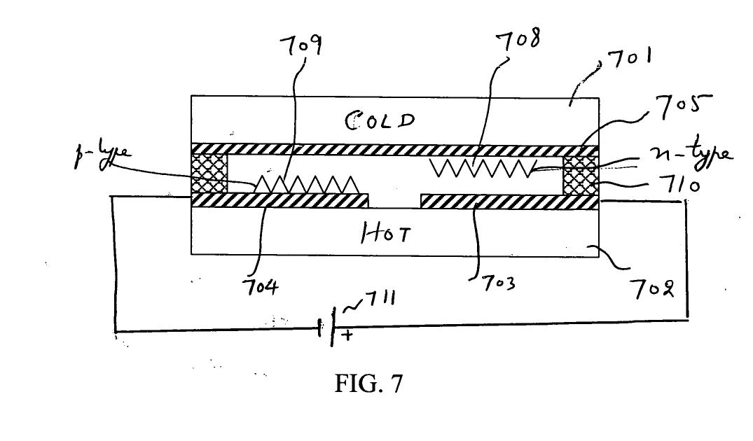

FIG. 7 shows another embodiment of the present invention.

### DETAILED DESCRIPTION OF THE INVENTION

A typical thermoelectric cooler (TEC) taught by prior art is depicted in FIG. 1. A TEC is based on the well known effect called Peltier Effect, by which electrical current provided by a power supply 110 is applied across two materials 106 and 108 through highly conducting metal electrodes 103, 104 and 105. Typically, one of the legs in the device comprises of n-type material as depicted by 108, while the other leg comprises of p-type material depicted by 106. In accordance with the Peltier Effect, heat is absorbed at one of the junctions called the heat source 101, and is transferred to the other side called the heat sink 102. This results in a temperature difference between the hot side and the cold side. However, materials 106 and 108 typically have substantial thermal conductivity resulting in direct heat loss from the hot side to the cold side. Higher the thermal conductivity of the thermoelectric materials, higher is the heat loss. As the temperature difference between the hot and cold side increases, this loss also increases until a point is reached that there is no net cooling effect. Thus there is a limit to the maximum temperature gradient that can be achieved across a thermoelectric device. This temperature difference is typically 30-40 degree centigrade.

FIG. 2 shows a block diagram of the present invention, where devices (called ‘thermal breaks’ herein) with high thermal resistivity and high electrical conductivity, depicted by 220, are inserted in the two legs 206 and 208 of the TEC. The orientation of the thermal breaks is such that they offer little or no resistance to the electrons flowing through the n-type and p-type materials in the TEC, while stopping most of the heat loss due to conduction through the n-type and p-type materials.

FIG. 3 shows a schematic diagram of a preferred embodiment of the above mentioned thermal breaks fabricated using standard vacuum microelectronics and field emission device technologies. 301 comprises either a metal plate or a metal layer formed on a glass or ceramic plate and forms the cathode contact of the device. Metal or semiconductor micro-tips 303 are form on the cathode layer, followed by a thin grid structure 302 fabricated on top of the tips 303 such that a small spacing on the order of 0.1-1 micrometers is maintained between the micro-tips and the grid. Another metal plate or metal layer coated glass/ceramic plate 302 is placed 1-1000 micrometers away from and parallel to the cathode plate. The gap between the two plates is uniformly maintained by insulating spacers 305 placed in between the two plates in such a way that the spacers 305 do not interfere with the flow of electrons 306 from the cathode 301 to the anode 302. In this device, typically the space between the anode and the cathode is evacuated and the device is vacuum sealed to avoid collisions between electrons and air/gas molecules. When a positive voltage is applied to the grid 302 with respect to the micro-tips 303, electrons are emitted from the tips due to high electric field created at the micro-tips (also called Spindt tips). Most of the emitted electrons pass through the holes in the grid reach the anode plate, thereby forming a continuous flow of current through the vacuum gap between the cathode plate and the anode plate. Under these conditions this device has a very low resistance between the cathode and the anode plates. At the same time, the thermal resistivity is very high due to the vacuum gap between the two plates and the only physical contact is through the spacers and the vacuum seal (shown as a part of the spacer) which have a very high thermal resistivity because they are fabricated from a thermally insulating material such as silicon dioxide or alumina. The tips can be made from either metals such as molybdenum, tungsten, nickel and copper, from semiconductors such as silicon, gallium arsenide and gemanium, or from other materials such as graphite, diamond, carbon nanotubes, or from a combination thereof.

FIG. 4 shows the electron flow through a thermoelectric device in accordance with the present invention. The electron emitter side of n-type semiconductor 406 is in thermal contact with the cold source while the electron emitter side of the p-type semiconductor 408 is in thermal contact with the hot source. In steady state, there is a continuous current with electrons emitted from the n-type semiconductor entering the hot source, while electrons emitted from of the p-type semiconductor enter the cold source. The difference in energy, Δε, of the two field emitted electrons is defined as
Δε=<εₙ>−<εₚ>, (2)
where <εₙ>and εₚ>are the average energies of the field emitted electrons from the n- and p-type semiconductors, respectively. The two thermal breaks in the path do not allow phonon conduction and there is no other thermal flow other than that associated with the electric or field emission current. Thus the net energy flow from the cold source to the hot source is just Δε. For the typical p-n junction, the energy levels of the conduction band of the n-type semiconductor are generally higher than that of the p-type semiconductor. This implies that Δε is positive. Thus, the mechanism for cooling is a field emission process. In this discussion, we can, as a first approximation, ignore traditional thermoelectric effects in the cooling process. The reason is that in good thermoelectric coolers, the cooling term, which is related to the entropy transport parameter, is on the order of about 50-60 meV per electron at room temperature. By contrast, the cooling device in accordance with the present invention has an energy transport (i.e., heat) per electron of 500-1,000 meV or so depending on concentration and field. For example, the energy carried by each electron going around the device is the difference of Fermi energies of the n-type and p-type semiconductors. In the case of silicon, this difference is almost 1,000 meV, almost equal to the bandgap of silicon. Thus, a cooling device in accordance with the present invention will carry 10-20 times more heat with the same amount of current flowing through the device.

The field emission based cooler will be electrically biased as shown in FIG. 5. If the electric current is I, then I/e is the number flux of particles (the number per unit time). The cooling efficiency η is operationally defined as the rate of heat removed from the cold source divided by the power input,

$$\begin{matrix}η = \frac{( I / e ) Δ ɛ}{I V} & ( 3 ) \\ = \frac{Δ ɛ}{e V} , & ( 4 )\end{matrix}$$

This shows that the device efficiency is no longer dependent on the ZT factor, because the thermal conductivity of the TE materials is no longer part of the equation. This equation also shows that the efficiency can be improved by decreasing the applied voltage V between the anode and the cathode. In addition, the over all device performance can be further improved by using a wide bandgap semiconductor to increase the Δε. For example use of n-type and p-type diamonmd will give a Δε on the order of 5 eV. Since it is difficult to fabricate n-type and p-type doped semiconductors from one wide bandgap material, it is possible to even use dissimilar materials as long as their Fermi energies are vastly different.

FIG. 5 shows a schematic diagram of a practical thermal break that can be used in a practical device. The cathode plate 501 comprises of a conducting metal plate or a ceramic plate coated with a metal layer 509 and forms one of the contacts to the thermal break. Similarly, 502 and 522 form the anode plate. Using standard lithography technology and widely known vacuum microelectronics fabrication technology, semiconductor micro-tips 503 and metal grid 504 are formed on the cathode metal layer 509. The two plates are separated using electrically and thermally insulating spacers 505 and sealed using frit sealing material 506. Again, this device structure is evacuated using standard techniques. The operation of the device is similar to that discussed earlier.

Another embodiment of the present invention is shown in FIG. 6, which is obtained by removing the grid 302 in the device shown in FIG. 3. The device structure depicted schematically is a two electrode configuration, forming a diode. It consists of two metal or ceramic plates 601 and 602 that form the cathode and the anode of the device, respectively. The cathode plate is coated with an electrically conducting layer 603, followed by fabrication of micro-tips 609, made from either metal, carbon nanotubes or silicon. One method for making these types of micro-tips has been described earlier by Kumar in U.S. Pat. No. 5,399,238. Again, the plates are separated by a suitable gap by using electrically and thermally insulating spacers 605, followed by sealing and evacuation of the device. In addition to the absence of the grid, another difference between diode and triode devices is the fact that the anode-cathode gap is very small in the diode devices, on the order of 100-1,000 nanometers (nm). While this is small as compared to the gap in triode devices, the diode gap is still very large as compared to 5-50 nm required by prior art diode type cooler devices taught by Edelson and Cox.

A similar modification to the triode device shown schematically in FIG. 4 is obtained by removing the grids 407 and 408. This essentially gives a complete diode device. However, it is possible to further simplify the device as shown in FIG. 7. In this embodiment of the invention, the p-type micro-tips 709 are fabricated on the metal contact 704 on the hot plate 702 of the cooler. The n-type micro-tips 708 are fabricated on the metal contact 705 in thermal contact with the cold plate 701. Again the two plates are attached together with proper spacers 710 and the device is properly sealed and evacuated. When an electric voltage is applied between the positive contact 703 and the negative contact 704 of the device, electrons are emitted from the n-type and p-type tips and the operation is very similar to that discussed for the device shown in FIG. 4. However, this device is much simpler to fabricate and there is no need to use complicated fabrication processes to fabricate thermoelectric material tips used in the prior art as described by Cooper et al. (U.S. Pat. No. 6,613,602 B2). The device in accordance with the present invention differs very significantly from that taught by Cooper et al. In the present invention, there is a significant gap (on the order of 100-1000 nm) between the tips and the opposite metal electrode (anode) and thus the present invention allows use of higher thermal conductivity semiconductors such as silicon and diamond tips to be used without loss of thermal performance of the device. As discussed earlier, use of n-type and p-type silicon enables large transfer of energy (almost equal to the bandgap of 1.1 eV) per electron from one side to the other side of the device, resulting in much higher performance.

When silicon tips are used, it is possible to obtain large emitted electron current density from these tips at an electric field of 0.5 MV/m (megavolts per meter). Using a device gap of 100 nm and a modest emitted current density of 1 ampere per square cm, we obtain a cooling capacity of almost 1 watt per square cm. Since the applied voltage is only 0.05 volts, the efficiency is almost 95% of the Carnot efficiency. This is much higher than 5-10% for prior art thermoelectric coolers and 40-50% for the mechanical coolers.

1. A device comprising an assembly containing a thermoelectric device and one or more other devices where these other devices act as electrically conducting but thermally insulating elements.

2. A device of claim 1, where the electrically conducting but thermally insulating elements are field emission devices.

3. A device of claim 1, where the electrically conducting but thermally insulating elements are triode type field emission devices.

4. A device of claim 1, where the electrically conducting but thermally insulating elements are diode type field emission devices.
